(19) United States
(12) Patent Application Publication
(10) Pub. No.: US 2007/0126114 A1
(43) Pub. Date: Jun. 7, 2007

(54) HEAT-DISSIPATING MEMBER, METHOD OF MANUFACTURING THE SAME, SEMICONDUCTOR MODULE HAVING THE HEAT-DISSIPATING MEMBER, AND METHOD OF MANUFACTURING THE SEMICONDUCTOR MODULE

(75) Inventors: Hee-Jin LEE, Gyeonggi-do (KR); Sun-Won KANG, Seoul (KR); Hae-Hyung LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/562,894

(22) Filed: Nov. 22, 2006

(30) Foreign Application Priority Data
Dec. 5, 2005 (KR) 2005-0117370

(51) Int. Cl. H01L 23/34; H01L 21/00

(52) U.S. Cl. 257/712; 257/E23.051; 438/125

(57) ABSTRACT

In one embodiment, a heat-dissipating member includes a heat-dissipating body, a heat-transferring body and an attaching member. The heat-dissipating body externally dissipates heat originating in a heat source. The heat-transferring member is interposable between the heat-dissipating body and the heat source. The attaching member is placed on a surface of the heat-dissipating body and corresponds to the heat-transferring body so as to couple the heat-transferring member to the heat-dissipating body. Thus, heat generated from the heat source, such as a semiconductor element, rapidly dissipates through the heat-transferring member and externally through the heat-dissipating body.

### CROSS-REFERENCE TO RELATED APPLICATIONS

This application claims priority under 35 USC §119 to Korean Patent Application No. 2005-117370 filed on Dec. 5, 2005, the contents of which are herein incorporated by reference in their entirety.

### BACKGROUND

1. Field of the Invention

The disclosure relates to a heat-dissipating member, a method of manufacturing the heat-dissipating member, a semiconductor module having the heat-dissipating member, and a method of manufacturing the semiconductor module. More particularly, the disclosure relates to a heat-dissipating member having improved heat dissipation efficiency, a method of manufacturing the heat-dissipating member, a semiconductor module having the heat-dissipating member, and a method of manufacturing the semiconductor module.

2. Description of the Related Art

A semiconductor device is manufactured by a semiconductor chip manufacturing process and a semiconductor chip packaging process, etc. Recently, the semiconductor device is widely used in various electronic instruments such as computers, cellular phones, MP3 players, etc. Generally, the semiconductor device generates heat in proportion to power consumption of the semiconductor device. The heat reduces a capacity of the semiconductor device. To rapidly dissipate the heat in the semiconductor device, a conventional semiconductor device has a heat-dissipating device for rapidly dissipating the heat in the semiconductor device.

In general, a conventional heat-dissipating device employed in the conventional semiconductor device commonly includes a heat dissipating plate for dissipating heat in the conventional semiconductor device. The heat-dissipating plate is fixed to the semiconductor device using a clip, a rivet, an adhesive member, etc.

However, when the conventional heat-dissipating plate is fixed to the semiconductor device using the clip, a printed circuit board (PCB) of the semiconductor device has a recess for receiving the clip so as to prevent the clip from being protruded from a side surface of the semiconductor device.

Further, when the conventional heat-dissipating plate is fixed to the semiconductor device using the rivet, it is required to form a hole through the PCB of the semiconductor device. The rivet is inserted into the hole to fix the heat-dissipating plate to the semiconductor device. The hole functions as to reduce an area of the PCB where conductive patterns are formed on the PCB.

### SUMMARY

In one embodiment, a heat-dissipating member includes a heat-dissipating body and a heat-transferring member interposable between the heat-dissipating body and a heat source. An attaching member located on a surface of the heat-dissipating body to couple the heat-transferring member to the heat-dissipating body.

### BRIEF DESCRIPTION OF THE DRAWINGS

The above and other features and advantages of the invention will become more apparent by describing in detail exemplary embodiments thereof with reference to the accompanying drawings, in which:

FIG. 1 is a cross-sectional view illustrating a heat-dissipating member in accordance with a first example embodiment;

FIG. 2 is a cross-sectional view illustrating an attaching member in FIG. 1;

FIG. 3 is a cross-sectional view illustrating a heat-dissipating member in accordance with a second example embodiment;

FIG. 4 is a cross-sectional view taken along line I-I′ in FIG. 3;

FIG. 5 is a flow chart illustrating a method of manufacturing a heat-dissipating member in accordance with a third example embodiment;

FIG. 6 is a cross-sectional view illustrating a heat-dissipating body of the heat-dissipating member in FIG. 5;

FIGS. 7 through 9 are cross-sectional views illustrating attaching members in accordance with another example embodiment;

FIG. 10 is a cross-sectional view illustrating the attaching member without a photoresist pattern in FIG. 9;

FIG. 11 is a cross-sectional view illustrating the attaching member in accordance with still another example embodiment;

FIGS. 12 and 13 are cross-sectional views illustrating a step for forming a heat-transferring member on the attaching member as shown in FIGS. 6 through 11;

FIG. 14 is a cross-sectional view illustrating a semiconductor module in accordance with a fourth example embodiment;

FIG. 15 is a cross-sectional view illustrating a semiconductor module in accordance with a fifth example embodiment;

FIG. 16 is a cross-sectional view illustrating a semiconductor module in accordance with a sixth example embodiment;

FIG. 17 is a cross-sectional view illustrating a semiconductor module in accordance with a seventh example embodiment;

FIG. 18 is a cross-sectional view illustrating a semiconductor module in accordance with an eighth example embodiment;

FIG. 19 is a cross-sectional view illustrating a semiconductor module in accordance with a ninth example embodiment;

FIG. 20 is a flow chart illustrating a method of manufacturing a semiconductor module in accordance with a tenth example embodiment;

FIG. 21 is a cross-sectional view illustrating a step for forming a heat-dissipating body and an attaching member of the semiconductor module;

FIG. 22 is an exploded cross-sectional view illustrating a step for assembling the heat-dissipating member with a circuit substrate using the heat-transferring member in FIG. 21;

FIG. 23 is a cross-sectional view illustrating a method of manufacturing a semiconductor module in accordance with an eleventh example embodiment;

FIG. 24 is an exploded cross-sectional view illustrating a method of manufacturing a semiconductor module in accordance with a twelfth example embodiment; and

FIG. 25 is an exploded cross-sectional view illustrating a method of manufacturing a semiconductor module in accordance with a thirteenth example embodiment.

### DETAILED DESCRIPTION OF EXEMPLE EMBODIMENTS

The invention is described more fully hereinafter with reference to the accompanying drawings, in which various embodiments of the invention are shown. This invention may, however, be embodied in many different forms and should not be construed as limited to the particular embodiments set forth herein. Rather, these embodiments are provided so that this disclosure will be thorough and complete, and will convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Heat-Dissipating Member

### Embodiment 1

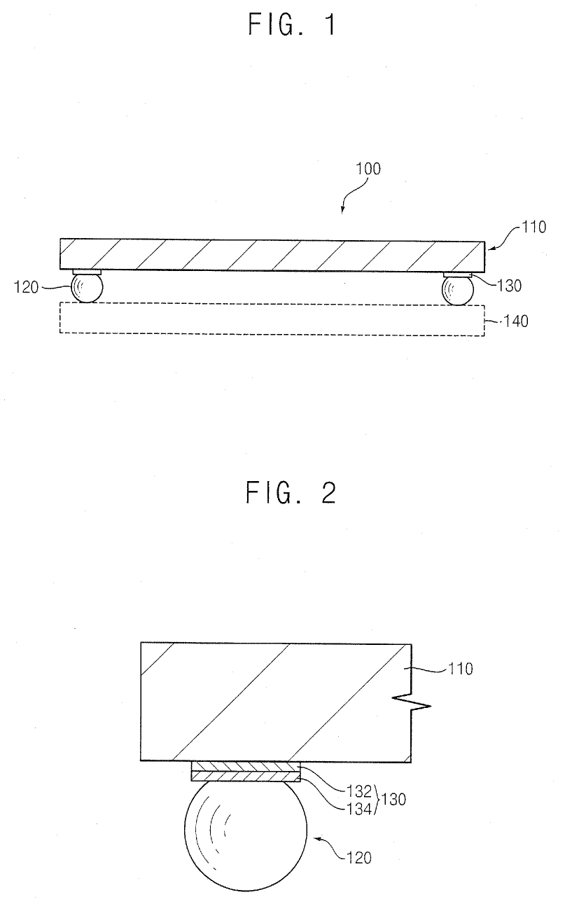

FIG. 1 is a cross-sectional view illustrating a heat-dissipating member according to a first example embodiment.

Referring to FIG. 1, a heat-dissipating member 100 includes a heat-dissipating body 110, a heat-transferring member 120 and an attaching member 130.

The heat-dissipating body 110 dissipates heat generated from a heat source 140, e.g., a semiconductor device generating heat during its operation, to outside. In this example embodiment, the heat-dissipating body 110 may include a material having a relatively high thermal conductivity. Examples of the material that may be used for the heat-dissipating body 110 include aluminum, aluminum alloy, copper, copper alloy and so on.

In this example embodiment, the heat-dissipating body 110 may have a substantially plate shape or a block shape. For example, the heat-dissipating body 110 may have a substantially rectangular plate shape or substantially square plate shape and so on.

Further, a concave-convex portion may be formed on the heat-dissipating body 110 so as to increase a surface area of the heat-dissipating body 110 and thereby to improve heat dissipation efficiency of the heat-dissipating body 110.

The heat-transferring member 120 is interposed between the heat source 140 and the heat-dissipating body 110 to rapidly transfer the heat in the heat source 140 to the heat-dissipating body 110. In addition, the heat-transferring member 120 couples the heat-dissipation body 110 to the heat source 140.

In this example embodiment, to efficiently transfer the heat from the heat source 140 to the heat-dissipating body 110, the heat-transferring member 120 may have a thermal conductivity greater than or approximately equal to that of the heat-dissipating body 110. Further, the heat-transferring member 120 may have a melting temperature lower than that of the heat-dissipating body 110 and the heat source 140 so as to couple the heat source 140 to the heat-dissipating body 110. Particularly, the heat-transferring member 120 may include a conductive material having a relatively high thermal conductivity and a relatively low melting temperature.

In this example embodiment, the heat-transferring member 120 may include a conductive body (not shown) having a relatively high thermal conductivity and a relatively low melting temperature. The heat-transferring member 120 may have a substantially spherical shape. Examples of a material that may be used for the heat-transferring member 120 include, but not limited to, solder, tin, tin alloy and so on. Particularly, in this example embodiment, the heat-transferring member 120 includes solder.

In this example embodiment, the heat-transferring member 120 having the substantially spherical shape may have a diameter of about 300 μm to about 3 mm. Further, the diameter of the heat-transferring member 120 may be adjusted in accordance with the gap between the heat source 140 and the heat-dissipating body 110.

When the heat-transferring member 120 includes solder and the heat-dissipating body 110 includes copper, it is difficult to attach the heat-transferring member 120 to the heat-dissipating body 110 due to the physical characteristics of copper.

In this example embodiment, the heat-transferring member 120 is combined with the heat-dissipating body 110 using the attaching member 130. The attaching member 130 is, therefore, interposed between the heat-transferring member 120 and the heat-dissipating body 110. In this example embodiment, the attaching member 130 may be placed on the surface of the heat-dissipating body 110.

The attaching member 130 placed on the heat-dissipating body 110 may have a single-layered structure. Examples of a material that may be used for the attaching member 130 having the single-layered structure include nickel, nickel alloy, gold, gold alloy, and so on.

In this example embodiment, the attaching member 130 may be partially formed on the heat-dissipating body 110. The attaching member 130 may be positioned on a portion of the heat-dissipating body 110 where the heat-transferring member 120 is to be formed. Alternatively, the attaching member 130 may be formed throughout substantially the entire surface of the heat-dissipating body 110 facing the heat-transferring member 120.

FIG. 2 is a cross-sectional view illustrating the attaching member in FIG. 1.

Referring to FIG. 2, the attaching member 130 placed on the heat-dissipating body 110 may have a double-layered structure. In this example embodiment, the attaching member 130 having the double-layered structure includes a first layer 132 and a second layer 134. Examples of a material that may be used for the first layer 132 of the attaching member 130 include nickel, nickel alloy, and so on. Further, examples of a material that may be used for the second layer 134 of the attaching member 130 include gold, gold alloy and so on.

In this example embodiment, the first layer 132 prevents the heat-dissipating body 110 having a relatively low melting temperature from being melted. Further, the second layer 134 enhances an adhesive force between the heat-transferring member 120 and the heat-dissipating body 110. Thus, the heat-transferring member 120 is firmly adhered to the surface of the heat-dissipating body 110 using the attaching member 130.

In this example embodiment, the attaching member 130 having the double-layered structure may be partially formed on the surface of the heat-dissipating body 110 corresponding to the heat-transferring member 120. Alternatively, the attaching member 130 having the double-layered structure may be formed throughout substantially the entire surface of the heat-dissipating body 110 facing the heat-transferring member 120.

According to the example embodiment, the heat generated from the heat source 140 is rapidly transferred to the heat-dissipating body 110 through the attaching member 130 and the heat-transferring member 120. The heat in the heat-dissipating body 110 may then be dissipated to the outside.

### Embodiment 2

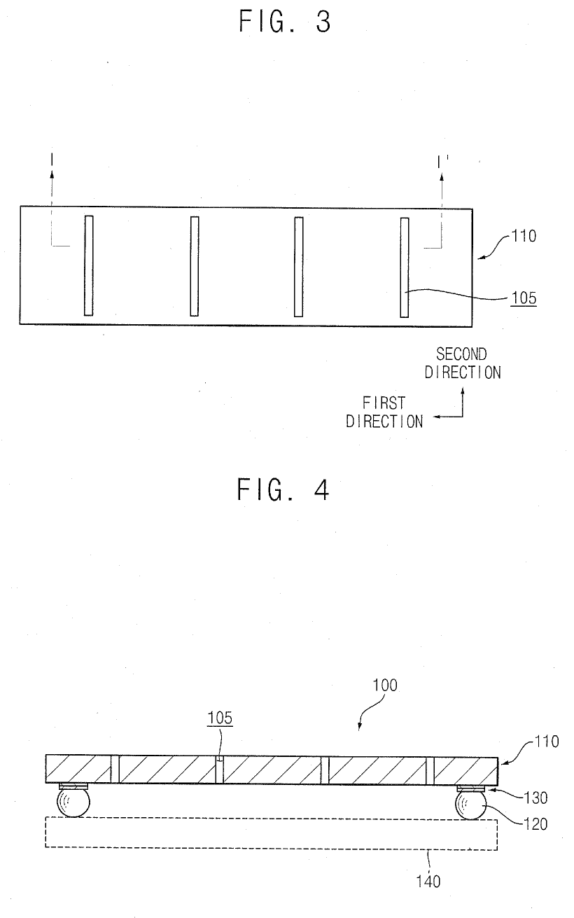

FIG. 3 is a cross-sectional view illustrating a heat-dissipating member in accordance with a second example embodiment. FIG. 4 is a cross-sectional view taken along line I-I′ in FIG. 3. The heat-dissipating member of the present embodiment includes elements substantially the same as those of the heat-dissipating member in FIGS. 1 and 2 except for openings 105 formed through the heat-dissipating body 110. Thus, any further illustrations of the same elements are omitted herein.

Referring to FIG. 3, a heat-dissipating member 100 includes the heat-dissipating body 110 having one or more openings 105 formed therethrough, the heat-transferring member 120, and the attaching member 130.

In the second example embodiment, the heat-dissipating body 110 includes a metal having a relatively high thermal conductivity. Examples of the metal that may be used for the heat-dissipating body 110 include aluminum, aluminum alloy, copper, copper alloy and so on. These metals expand or contract by heating or cooling. An expansion/contraction rate of the heat-dissipating body 110 is proportional to a dimension of the heat-dissipating body 110. For example, the expansion/contraction rate of the heat-dissipating body 110 is proportional to a length of the heat-dissipating body 110.

When the heat-dissipating body 110 may have a substantially rectangular parallelepiped shape, the heat-dissipating body 110 has a pair of long sides facing each other and a pair of short sides facing each other. Thus, the heat-dissipating body 110 having the substantially rectangular parallelepiped shape mainly expands or contracts along a first direction substantially in parallel with the long sides of the heat-dissipating body 110.

In this example embodiment, to suppress the expansion and/or the contraction of the heat-dissipating body 110, the openings 105 are formed through the heat-dissipating body 10. The openings 105 may have a slit shape in plan view. Further, the number of the opening 105 may be at least one as indicated above. The opening 105 having the slit shape may be arranged in a second direction substantially perpendicular to the first direction. Alternatively, the opening 105 may have various shapes such as an elliptical shape, a circular shape, a rectangular shape, a polygonal shape, etc., as well as the slit shape in plan view.

Since the opening 105 having slit shape reduces a total length of the heat-dissipating body 110, an expansion/contraction length of the heat-dissipating body 110 is significantly reduced. Thus, although the heat-transferring member 120 attached to the heat-dissipating body 110 is physically connected to the heat source 140, the heat-transferring member 120, the heat-dissipating body 110 and the heat source 140 may not be damaged due to the expansion/contraction of the heat-dissipating body 110.

Method of Manufacturing the Heat-Dissipating Member

### Embodiment 3

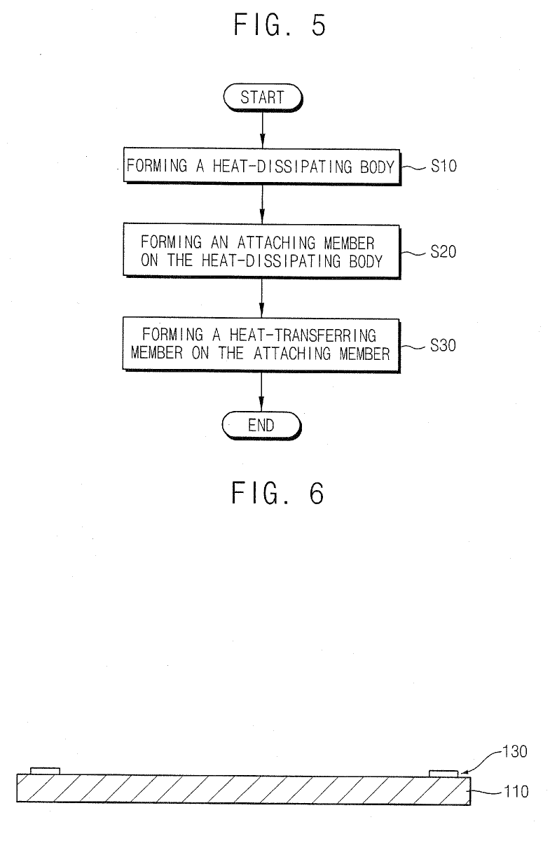

FIG. 5 is a flow chart illustrating a method of manufacturing a heat-dissipating member in accordance with a third example embodiment. FIG. 6 is a cross-sectional view illustrating a heat-dissipating body of the heat-dissipating member in FIG. 5.

Referring to FIGS. 5 and 6, to manufacture a heat-dissipating member of the third example embodiment, in step S10, first of all, a heat-dissipating body 110 for rapidly dissipating heat in a heat source is prepared.

In this example embodiment, the heat-dissipating body 110 may have a substantially plate shape. Particularly, the heat-dissipating body 110 may have a substantially rectangular parallelepiped shape or a substantially square plate shape. For example, the heat-dissipating member has a substantially rectangular parallelepiped shape. Examples of a material that may be used for the heat-dissipating body 110 include aluminum, aluminum alloy, copper, copper alloy and so on.

Although not illustrated, after forming the heat-dissipating body 110, a concave-convex portion for increasing heat dissipation efficiency may be formed on the heat-dissipating body 110.

FIG. 6 is a cross-sectional view illustrating one example embodiment of an attaching member in FIG. 5.

Referring to FIGS. 5 and 6, after forming the heat-dissipating body 110, an attaching member 130 may be formed on a surface of the heat-dissipating body 110. In this example embodiment, the attaching member 130 couples, e.g., attaches a heat-transferring member described later to a surface of the heat-dissipating body 110.

In this example embodiment, the attaching member 130 may be formed on the heat-dissipating body 110 by various processes such as a plating process, photolithography process for processing a thin film, an adhesion process using an adhesive material and so on. Further, the attaching members 130 formed on the heat-dissipating body 110 may have a single-layered structure. When the attaching member 130 having the single-layered structure is formed on the heat-dissipating member 110, examples of a material that may be used for the attaching member 130 include nickel, nickel alloy, gold, gold alloy and so on.

In this example embodiment, the attaching member 130 having the single-layered structure may be formed on a portion of the heat-dissipating body 110. Alternatively, the attaching member 130 having the single-layered structure may be formed on substantially the entire surface of the heat-dissipating body 110.

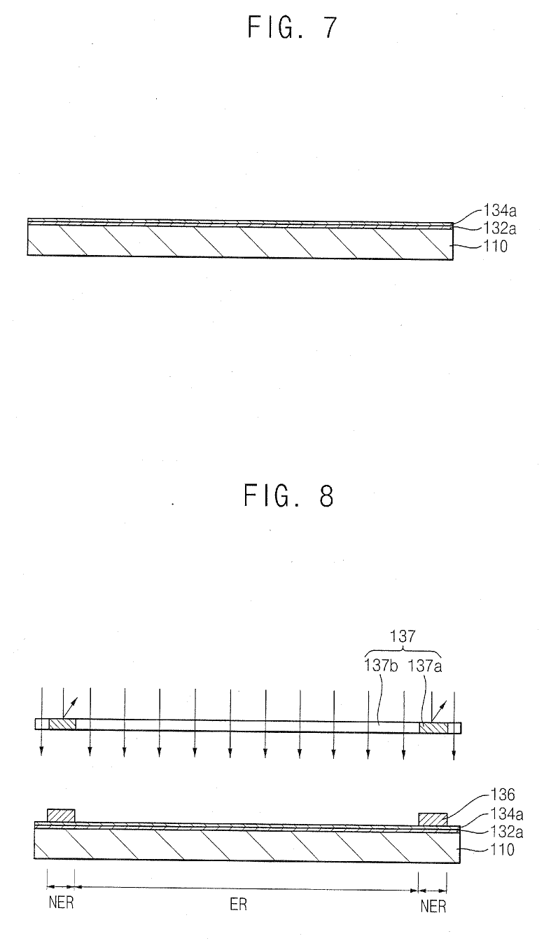

FIGS. 7 through 9 are cross-sectional views illustrating attaching members in accordance with another example embodiment.

Referring to FIGS. 5 and 7, to form an attaching member 130 on the heat-dissipating body 110, in step S20 of FIG. 5, a first layer 132a is formed on an upper surface of the heat-dissipating body 110. The first layer 132a may be formed by conventional thin film deposition processes such as a chemical vapor deposition (CVD) process, a physical vapor deposition (PVD) process such as a sputtering process or a plating process. Examples of a material that may be used for the first layer 132a include nickel, nickel alloy and so on. In this example embodiment, the first layer 132a prevents the heat-dissipating body 110 having a relatively low melting temperature from being melted due to a relatively high temperature during the subsequent processing steps.

After forming a first layer 132a on the surface of the heat-dissipating body 110, a second layer 134a is sequentially formed on an upper surface of the first layer 132a. In this example embodiment, the second layer 134a may be formed by a CVD process, a PVD process such as a sputtering process, a plating process and so on. Examples of a material that may be used for the second layer 134a include gold, gold alloy and so on. In this example embodiment, the second layer 134a enhances an adhesive force between a heat-transferring member described later and the heat-dissipating body 110. The second layer may suppress an oxidation of the upper surface of the first layer 132a.

In this example embodiment, the first layer 132a and the second layer 134a may be used as the attaching members 130 without being patterned.

Referring to FIG. 8, a photosensitive photoresist film (not shown) is then formed on an upper surface of the second layer 134a. The photosensitive photoresist film may be formed by, for example, a spin coating process. In this example embodiment, the photosensitive photoresist film may include a positive photosensitive photoresist substance.

After forming the photosensitive photoresist film on the second layer 134a, a reticle 137 is then placed over the photosensitive photoresist film. The reticle 137 includes a light absorbing portion 137a and a light transmitting portion 137b. A light beam passing through the light transmitting portion 137b of the reticle 137 is irradiated to the photosensitive photoresist film, so that a portion of the photosensitive photoresist film is exposed by the light beam. Thus, the photosensitive photoresist film is divided into an exposed region ER and a non-exposed region NER. The exposed region ER is enclosed by the non-exposed region NER.

The photosensitive photoresist film having the exposed region ER and the non-exposed region NER is developed by a developing solution. When the photosensitive photoresist film is developed by the developing solution, a solubility of the exposed region ER with respect to the developing solution is relatively higher than that of the non-exposed region NER because the positive photosensitive photoresist substance in the exposed region ER is reacted with the light beam. Thus, the photosensitive photoresist film in the exposed region ER is removed from the upper surface of the second layer 134a to form a photoresist pattern 136 on the second layer 134a.

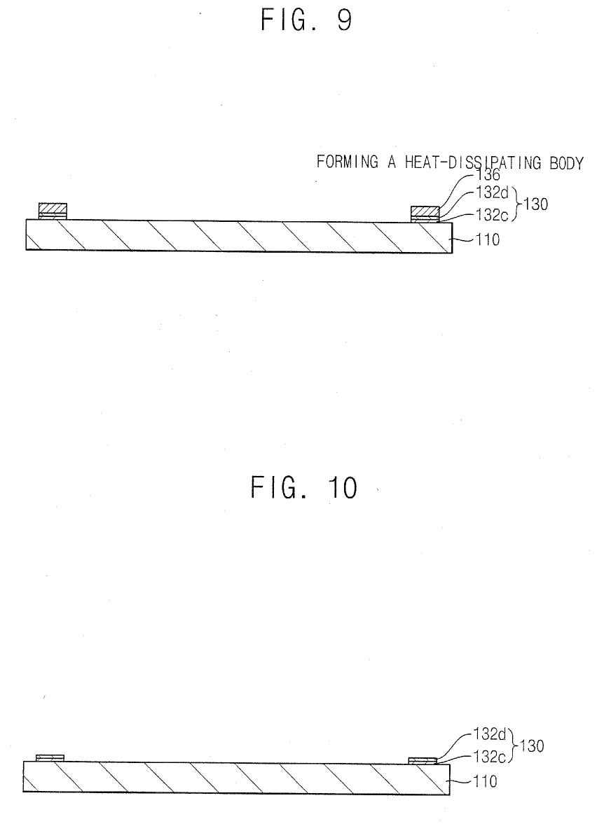

FIG. 9 is a cross-sectional view illustrating first and second attaching patterns that are formed by etching the first and second layers.

Referring to FIGS. 8 and 9, after forming the photoresist pattern 136 as shown in FIG. 8, the first layer 132a and the second layer 134a are etched using the photoresist pattern 136 as an etching mask to form an attaching member 130 on the heat-dissipating body 110. The attaching member 130 includes a first attaching pattern 132c and a second attaching pattern 132d. The second attaching pattern 132d may be formed on an upper surface of the first attaching pattern 132c.

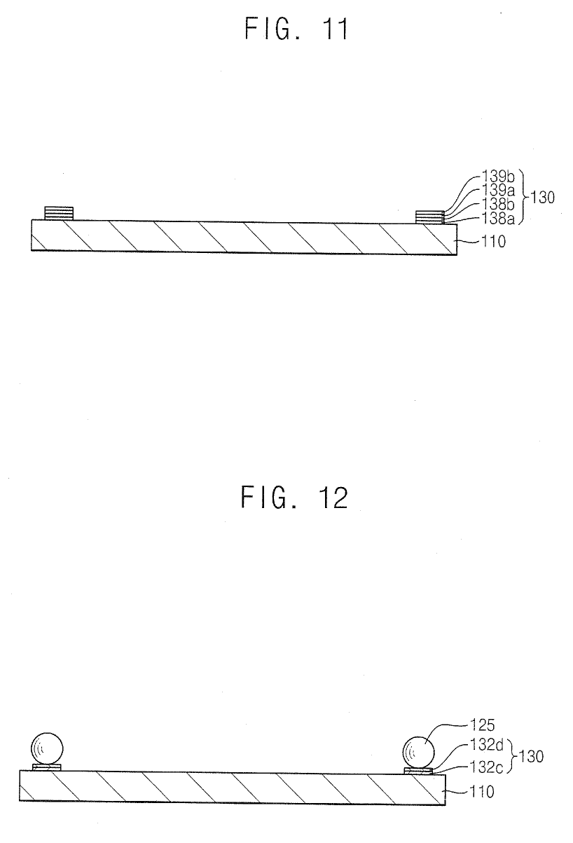

Referring to FIGS. 9 and 10, the photoresist pattern 136 placed on an upper surface of the attaching member 130 is removed from the attaching member 130. In this example embodiment, the photoresist pattern 136 may be removed by an ashing process using O₂ plasma and/or a stripping process.

FIG. 11 is a cross-sectional view illustrating an attaching member 130 in accordance with still another example embodiment.

Referring to FIG. 11, the attaching member 130 includes a first adhesive member 138a, a first layer 138b, a second adhesive member 139a, and a second layer 139b.

The first adhesive member 138a is attached to an upper surface of the heat-dissipating body 110. The first layer 138b, which may include a metal having a relatively high thermal conductivity, is placed on the first adhesive member 138a.

The second adhesive member 139a is attached to an upper surface of the first layer 138b. The second layer 139b, which may include a metal having a relatively high thermal conductivity, is placed on the second adhesive member 139a. The first and second adhesive members 138a and 139a may have a thermal conductivity substantially the same as that of at least one of the first and second layers 138b and 139b. For example, the first and second adhesive members 138a and 139a may have a first thermal conductivity substantially similar to a second thermal conductivity of the first and second layers 138b and 139b. The first layer 138b and the second layer 139b may include various conductive materials such as metals having a relatively high thermal conductivity. Alternatively, after the first layer 138b is formed on the heat-dissipating body 110 using the first adhesive member 138a, the second layer 139b may be directly formed on the upper surface of the first layer 138b without the second adhesive member 139a.

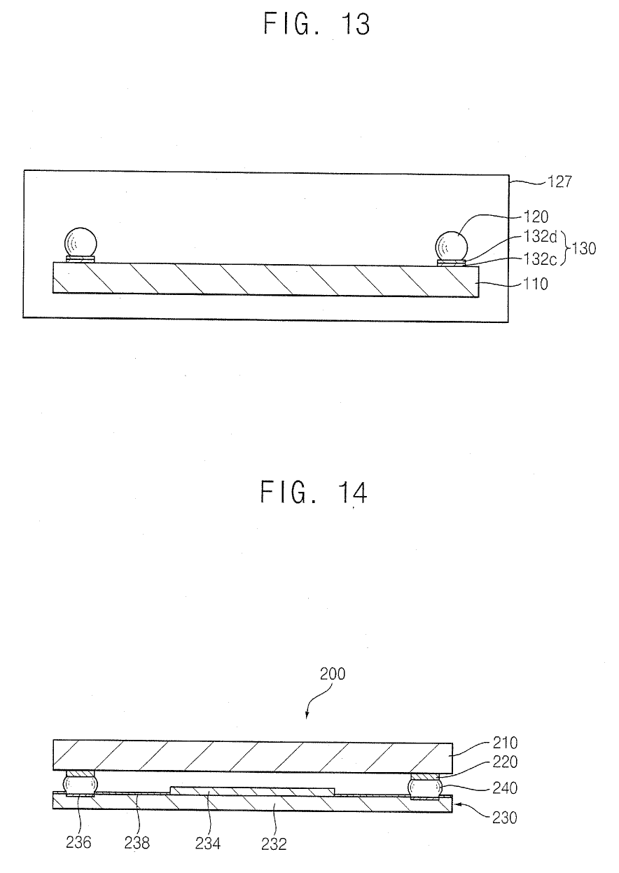

FIGS. 12 and 13 are cross-sectional views illustrating the formation of a heat-transferring member on the attaching member as shown in FIGS. 6 through 11.

Referring back to FIGS. 5 and 12, in step S30, a conductive member 125, which functions as a heat-transferring member 120 of FIG. 1, is placed on the upper surface of the attaching member 130. In this example embodiment, the conductive member 125 may have a thermal conductivity substantially similar to that of the heat-dissipating body 110.

Examples of a material that may be used for the conductive member 125 include gold, silver, copper, solder and so on. In this example embodiment, the conductive member 125 includes solder having a melting temperature lower than that of the heat-dissipating body 110 and a thermal conductivity substantially similar to that of the heat-dissipating body 110.

Additionally, the conductive member 125 may have a substantially columnar shape or a substantially spherical shape and so on. In this example embodiment, the conductive member 125 has the substantially spherical shape. However, the conductive member 125 may have a shape other than the shapes described above within the spirit and scope of the present invention.

The conductive member 125 having the substantially spherical shape is placed on the attaching member 130. A thin flux layer (not shown) may be interposed between the conductive member 125 and the attaching member 130. That is, the conductive member 125 may be attached to the attaching member 130 using the flux layer.

Referring to FIG. 13, the heat-dissipating body 110 having the conductive member 125 of FIG. 12 is loaded into a furnace such as an infrared reflow furnace 127. After loading the heat-dissipating body 110 into the reflow furnace 127, a portion of the conductive member 125 attached to the attaching member 130 is melted by heat generated from the reflow furnace 127, thereby forming a heat-transferring member 120 coupled to the attaching member 130. During this process, a boundary surface between the conductive member 125 and the attaching member 130 may be melted.

In this example embodiment, the heat-transferring member 120 is selectively formed only on the upper surface of the attaching member 130. Alternatively, the heat-transferring member 120 covers side surfaces of the attaching member 130 as well as the upper surface of the attaching member 130.

Semiconductor Module

### Embodiment 4

FIG. 14 is a cross-sectional view illustrating a semiconductor module in accordance with a fourth example embodiment.

Referring to FIG. 14, a semiconductor module 200 includes a heat-dissipating body 210, an attaching member 220, a circuit substrate 230, and a heat-transferring member 240.

The heat-dissipating body 210 may have a substantially plate shape. Further, the heat-dissipating body 210 may have a relatively high thermal conductivity. Examples of a material that may be used for the heat-dissipating body 210 include aluminum, aluminum alloy, copper, copper alloy and so on.

The attaching member 220 is placed on a lower surface of the heat-dissipating body 210. The attaching member 220 couples the heat-transferring member 240, which has a relatively low adhesive force with respect to the heat-dissipating body 210, with the heat-dissipating body 210.

The attaching member 220 may have a single-layered structure. Examples of a material that may be used for the attaching member 220 having the single-layered structure include nickel, nickel alloy, gold, gold alloy, etc. For example, the attaching member 220 having the single-layered structure may be placed on substantially the entire surface of the heat-dissipating body 210. Alternatively, the attaching member 220 having the single-layered structure is formed on a portion of the heat-dissipating body 210.

According to another aspect of the present invention, the attaching member 220 may have a double-layered structure. The attaching member 220 having the double-layered structure may include a first layer and a second layer. The first layer is directly formed on the lower surface of the heat-dissipating body 210. The second layer is formed on a lower surface of the first layer. In this example embodiment, examples of a material that may be used for the first layer include nickel, nickel alloy and so on. Further, examples of a material that may be used for the second layer include gold, gold alloy and so on. Here, the attaching member 220 having the double-layered structure is formed throughout substantially the entire surface of the heat-dissipating body 210. Alternatively, the attaching member 220 having the double-layered structure is formed on a portion of the heat-dissipating body 210.

The circuit substrate 230 faces the heat-dissipating body 210. The circuit substrate 230 includes a substrate body 232, an element 234 formed on the substrate body 232, a land pattern 236 formed on a portion of the substrate body 232 where the attaching member 220 is to be formed, and a photo solder resist (PSR) film 238 for insulating the substrate body 232 from an external conductive body (not shown).

The substrate body 232 may include a printed circuit board (PCB). In this example embodiment, the substrate body 232 may have a substantially rectangular parallelepiped shape.

The element 234 is mounted on the substrate body 232. In this example embodiment, the element 234 may include a chip scale package (CSP) such as a ball grid array (BGA) package, a wafer level (W/L) package and so on. Alternatively, the element 234 may include various electronic instruments that generate heat while operating.

The land pattern 236 is formed on the substrate body 232. The land pattern 236 is electrically insulated from the element 234. A material that may be used for the land pattern 236 may be substantially similar to that of a conductive pattern (not illustrated) formed on the substrate body 232. Examples of a material metal that may be used for the land pattern 236 include copper, copper alloy, aluminum, aluminum alloy and so on.

The PSR 238 insulates the conductive pattern formed on the substrate body 232 from the external conductive body. Further, the PSR has an opening for exposing the land pattern 236 formed on the substrate body 232. In this example embodiment, the land pattern 236 is positioned below the PSR 238. Alternatively, the land pattern 236 may be placed on an upper surface of the PSR 238.

In this example embodiment, the heat-transferring member 240 rapidly transfers heat generated from the element 234 to the heat-dissipating body 210 to decrease a temperature of the element 234. In addition, the heat-transferring member 240 firmly combines the heat-dissipating body 210 with the circuit substrate 230.

The heat-transferring member 240 is interposed between the land pattern 236 of the substrate body 232 and the attaching member 220 formed on the heat-dissipating body 210. In this example embodiment, the heat-transferring member 240 may have a substantially columnar shape or a substantially spherical shape. For example, the heat-transferring member 240 has the substantially spherical shape. The heat-transferring member 240 may have a diameter of about 300 μm to about 3 mm. In this example embodiment, examples of a material that may be used for the heat-transferring member 240 include solder, solder alloy and so on.

The land pattern 236 of the substrate body 232 is coupled to the attaching member 220 of the heat-dissipating body 210 through the heat-transferring member 240.

According to the present embodiment, the attaching member 220 having an adhesive force higher than that of the heat-transferring member 240 is adhered to the heat-dissipating body 210. Since the attaching member 220 and the land pattern 236 of the substrate body 232 are coupled, e.g., electrically and physically connected to the heat-transferring member 240, heat generated from the element 234 mounted on the circuit substrate 230 is rapidly transferred to the heat-dissipating body 210 without degrading the characteristics of the circuit substrate 230.

### Embodiment 5

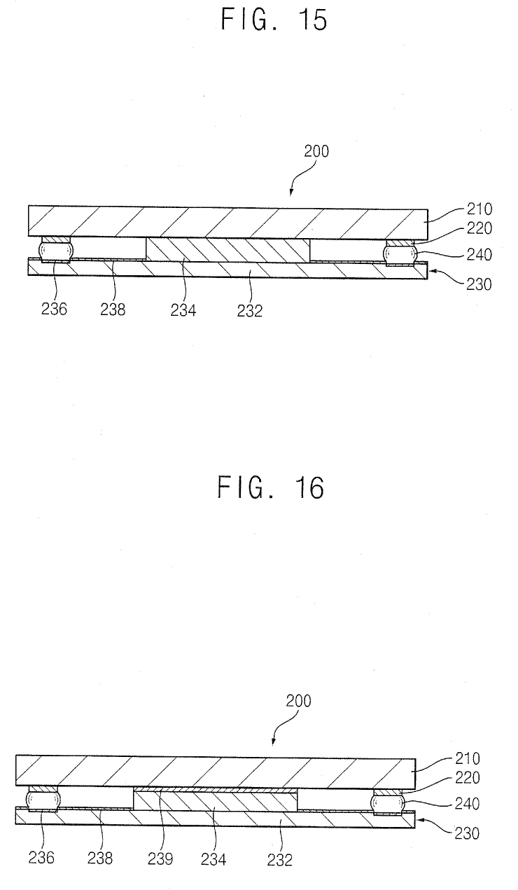

FIG. 15 is a cross-sectional view illustrating a semiconductor module in accordance with a fifth example embodiment. The semiconductor module of the present embodiment includes elements substantially the same as those of the semiconductor module in Embodiment 4 except for a distance between the heat-dissipating body 210 and the element 234. Thus, the same reference numerals refer to the same elements and any further illustrations of the same elements are omitted herein.

Referring to FIG. 15, a semiconductor module 200 includes the heat-dissipating body 210, the attaching member 220, the circuit substrate 230, and the heat-transferring member 240.

When the heat-dissipating body 210 and the element 234 mounted on the circuit substrate 232 are spaced apart from each other, heat dissipation efficiency in the element 234 may be decreased.

In this example embodiment, to greatly enhance the heat dissipation efficiency in the element 234, the heat-dissipating body 210 is closely adhered to, e.g., in direct contact with, an upper surface of the element 234 mounted on the circuit substrate 232. Thus, a height of the heat-transferring member 240 measured from the heat-dissipating body 210 to the circuit substrate 232 is substantially the same as the thickness of the element 234.

According to the present embodiment, because the element 234 mounted on the circuit substrate 232 is in direct contact with the heat-dissipating body 210, the heat dissipation efficiency in the element 234 may be greatly increased. Additionally, as the element 234 is in direct contact with the heat-dissipating body 210, leaving no space therebetween, the thickness of the semiconductor module 200 may be significantly reduced.

### Embodiment 6

FIG. 16 is a cross-sectional view illustrating a semiconductor module in accordance with a sixth example embodiment. The semiconductor module of the present embodiment includes elements substantially the same as those of the semiconductor module in Embodiment 4 except for a heat-dissipating sheet 239 interposed between the heat-dissipating body 210 and the element 234. Thus, the same reference numerals refer to the same elements and any further illustrations of the same elements are omitted herein.

Referring to FIG. 16, a semiconductor module 200 includes the heat-dissipating body 210, the attaching member 220, the circuit substrate 230, the heat-transferring member 240, and the heat-transferring sheet 239.

In this example embodiment, the heat-transferring sheet 239 is interposed between the heat-transferring body 210 and the element 234 mounted on the circuit substrate 230. The heat-transferring sheet 239 rapidly transfers heat in the element 234 to the heat-dissipating body 210. Thus, a first surface of the heat-transferring sheet 239 is attached to the element 234 and a second face of the heat-transferring sheet 239 opposite to the first surface is attached to the heat-dissipating body 210.

In this example embodiment, the heat-transferring sheet 239 may have a substantially sheet shape.

In one aspect, the heat-transferring sheet 239 may be formed only on the upper surface of the element 234. Alternatively, the heat-transferring sheet 239 may be attached to both the upper surface and side surfaces of the element 234.

In this example embodiment, the heat-transferring sheet 239 may have a thermal conductivity substantially similar to that of the heat-dissipating body 210 and/or the heat-transferring member 240.

### Embodiment 7

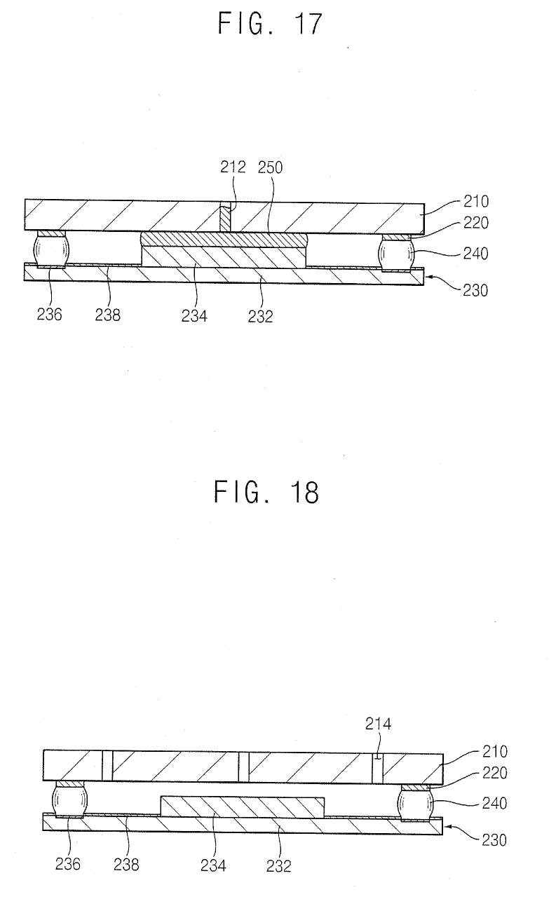

FIG. 17 is a cross-sectional view illustrating a semiconductor module in accordance with a seventh example embodiment. The semiconductor module includes elements substantially the same as those of the semiconductor module in Embodiment 4 except for a heat-transferring layer 250 interposed between the heat-dissipating body 210 and the element 234 and a hole formed through the heat-dissipating body 210. Thus, the same reference numerals refer to the same elements and any further illustrations of the same elements are omitted herein.

Referring to FIG. 17, a semiconductor module 200 includes the heat-dissipating body 210, the attaching member 220, the circuit substrate 230, the heat-transferring body 240, and the heat-transferring layer 250.

The heat-transferring layer 250 is interposed between the heat-dissipating body 210 and the circuit substrate 230. The heat-transferring layer 250 rapidly transfers heat generated from the element 234 to the heat-dissipating body 210. The heat-transferring layer 250 of the present embodiment may have a concave-convex portion such as recesses, grooves, and protrusions, etc to greatly enhance heat dissipation efficiency of the element 234.

In this example embodiment, the heat-transferring layer 250 may include a material having a relatively high thermal conductivity. For example, the heat-transferring layer 250 may be formed by injecting a fluid conductive material into a gap between the heat-dissipating body 210 and the circuit substrate 230. To inject the fluid conductive material into the gap, at least one hole 212 is formed through the heat-dissipating body 210 corresponding to the upper surface of the element 234.

In this example embodiment, the heat-transferring layer 250 may be placed only on the upper surface of the element 234. Alternatively, the heat-transferring layer 250 may be formed on side surfaces of the element 234 as well as the upper surface of the element 234.

### Embodiment 8

FIG. 18 is a cross-sectional view illustrating a semiconductor module in accordance with an eighth example embodiment. The semiconductor module includes elements substantially the same as those of the semiconductor module in Embodiment 4 except for a heat-dissipating body 210. Thus, the same reference numerals refer to the same elements and any further illustrations of the same elements are omitted herein.

Referring to FIG. 18, a semiconductor module 200 includes the heat-dissipating body 210, the attaching member 220, the circuit substrate 230, and the heat-transferring member 240.

The heat-dissipating body 210 is coupled with the circuit substrate 230 using the heat-transferring member 240. Thus, heat generated from the element 234 mounted on the circuit substrate 230 is transferred from the element 234 to the heat-dissipating body 210 through the heat-transferring member 240.

In this example embodiment, the heat-dissipating body 210 includes a metal having a relatively high thermal expansion coefficient. The circuit substrate 230 and the element 234 include a metal having a relatively low thermal expansion coefficient.

Thus, the heat-dissipating body 210 expands by a first length in a lengthwise direction of the heat-dissipating body 210 due to the heat generated from the element 234. Further, the circuit substrate 230 and the element 234 expand by a second length, which is shorter than the first length in a lengthwise direction of the circuit substrate 230 and the element 234, due to the heat. Therefore, a shear force is applied to the heat-transferring member 240 for tightly combining the heat-dissipating body 210 with the circuit substrate 230 due to a difference between the thermal expansion coefficients of the heat-dissipating body 210 and the circuit substrate 230. As a result, the heat-transferring member 240, the heat-dissipating body 210 and/or the circuit substrate 230 may be damaged or destroyed due to the shear force applied thereto.

In this example embodiment, to prevent the heat-dissipating body 210, the circuit substrate 230, and the heat-transferring member 240 from being damaged by the shear force, at least one opening having a slit shape is formed through the heat-dissipating body 210.

In this example embodiment, the heat-dissipating body 210 may have a substantially rectangular shape in plan view. The heat-dissipating body 210 includes a pair of long sides having a first thermal expansion coefficient, and a pair of short sides having a second thermal expansion coefficient less than the first thermal expansion coefficient. Thus, the opening 214 having the slit shape may be formed in a direction substantially in parallel with the short sides. Alternatively, the opening 214 having the slit shape may be formed in a direction substantially in parallel with the long sides. Further, the opening 214 having the slit shape may be formed in the direction substantially in parallel with the long or short sides.

According to the present embodiment, the semiconductor module 200 may not be damaged due to the difference between the thermal expansion coefficients of the heat-dissipating body 210 and the circuit substrate 230.

### Embodiment 9

FIG. 19 is a cross-sectional view illustrating a semiconductor module in accordance with a ninth example embodiment. The semiconductor module of the present embodiment includes elements substantially the same as those of the semiconductor module in Embodiment 4 except for an element 260. Thus, the same reference numeral refers to the same elements and any further illustrations of the same elements are omitted herein.

Referring to FIG. 19, a semiconductor module 200 includes the heat-dissipating body 210, the attaching member 220, the circuit substrate 230, and the heat-transferring member 240.

The element 260 mounted on the circuit substrate 230 may include a semiconductor package that includes a package substrate 262, a semiconductor chip 264, and conductive balls 265 formed under the package substrate 262.

The package substrate 262 may be a known package substrate such as a flexible polyimide substrate or a printed circuit board (PCB). However, one skilled in the art will appreciate that other substrates can be used if they are suitable for forming a semiconductor package. The semiconductor chip 264 is mounted on the substrate 262. A bonding pad formed on an upper surface of the semiconductor chip 264 may be electrically coupled to a conductive pattern (not shown) formed on the substrate 262 using, for example, a conductive wire (not shown).

The conductive balls 265 are electrically connected to the substrate 262. The conductive chip balls 265, among other functions, input an external signal into the semiconductor chip 264 or output a data signal processed by the semiconductor 264 to outside. The conductive ball 265 is also electrically coupled to the circuit substrate 230.

According to another aspect, two or more such semiconductor packages may be vertically stacked to form a multi-stacked package (MSP). The MSP may include a connecting member 266 for electrically connecting adjacent two semiconductor packages to each other. Further, in the MSP, the heat-transferring member 240 is disposed on the semiconductor package that is nearest to the heat-dissipating body 210. The heat-transferring member 240 is electrically connected to the attaching member 220 formed on the heat-dissipating body 210.

Method of Manufacturing the Semiconductor Module

### Embodiment 10

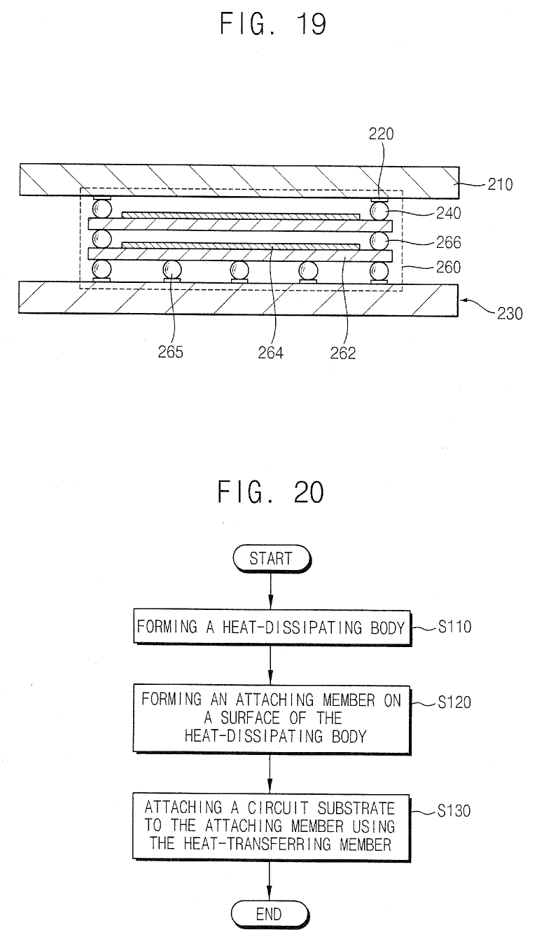

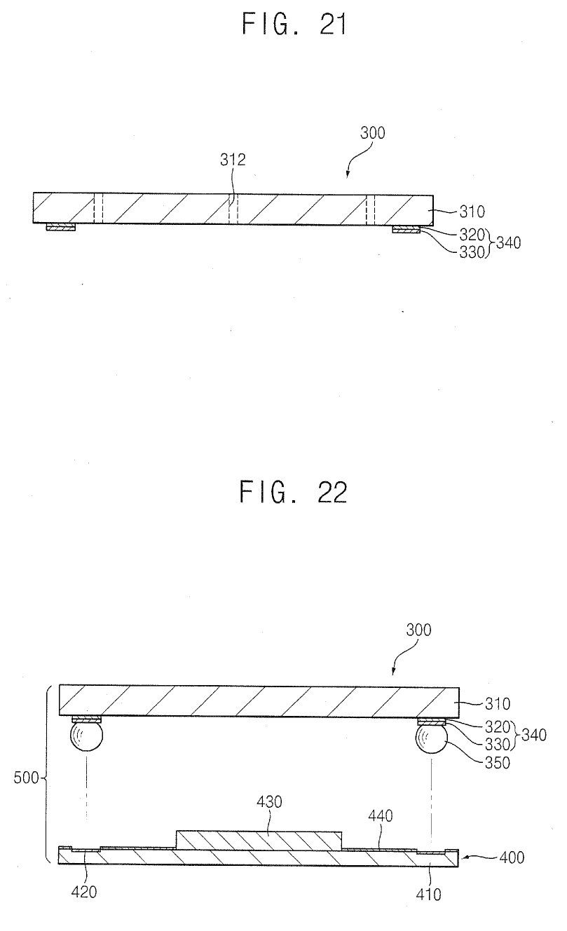

FIG. 20 is a flow chart illustrating a method of manufacturing the semiconductor module in accordance with a tenth example embodiment. FIG. 21 is a cross-sectional view illustrating processing steps for forming a heat-dissipating body and an attaching member of the semiconductor module.

Referring to FIGS. 20 and 21, in step S110 and S120, the heat-dissipating member 300 for rapidly dissipating heat generated from a heat source is formed.

To manufacture the heat-dissipating member 300, a heat-dissipating body 310 having a relatively high thermal conductivity is provided. In this example embodiment, one or more openings 312 each having a slit shape may be formed through the heat-dissipating body 310 to suppress an expansion of the heat-dissipating body 310 due to the heat generated from the heat source. In this example embodiment, at least two openings 312 may be arranged in parallel to each other.

In step S120, an attaching member 340 is formed on a portion of the heat-dissipating body 310 to form the heat-dissipating member 300. The attaching member 340 may include a first layer 320 having nickel and a second layer 330 having gold. Alternatively, the attaching member 340 may be formed substantially the entire surface of the heat-dissipating body 310. Further, the attaching member 340 may have a single-layered structure. For example, the attaching member 340 may include any one of the first layer 320 and the second layer 330. Furthermore, the attaching member 340 may be formed by attaching the first layer 320 including an adhesive and/or the second layer 330 including an adhesive to the heat-dissipating member 310.

In step S130 illustrated in FIG. 20, the attaching member 340 is attached to a circuit substrate using a heat-transferring member 350 shown in FIG. 22.

FIG. 22 is an exploded cross-sectional view illustrating a processing step for coupling the heat-dissipating member 300 with a circuit substrate 400 using, for example, the heat-transferring member 350.

Referring to FIG. 22, after forming the attaching member 340 on the heat-dissipating body 310, the heat-transferring member 350 having a substantially spherical shape is formed on the attaching member 340. The heat-transferring member 350 is partially melted in the infrared reflow furnace (not shown). The melted heat-transferring member 350 is thus firmly attached to the attaching member 340.

After attaching the heat-transferring member 350 to the attaching member 340, the heat-transferring member 350 is aligned with a land pattern 420 formed on the circuit substrate 400. A photo solder resist (PSR) is formed on the circuit substrate 400. The PSR has an opening that exposes the land pattern 420. An element 430 such as a semiconductor package is mounted on the circuit substrate 400.

The heat-transferring member 350 attached to the attaching member 340 may be partially melted in an infrared reflow furnace. Thus, the heat-transferring member 350 can be firmly combined with the land pattern 420 to complete the semiconductor module 500.

According to the present embodiment, the heat-transferring member 350 is attached to the attaching member 340 formed on the heat-dissipating body 310 by a reflow process. The heat-transferring member 350 is then attached to the land pattern 420 by a following reflow process. Thus, the element 430 mounted to the circuit substrate 400 may not be damaged due to heat in the infrared reflow furnace.

### Embodiment 11

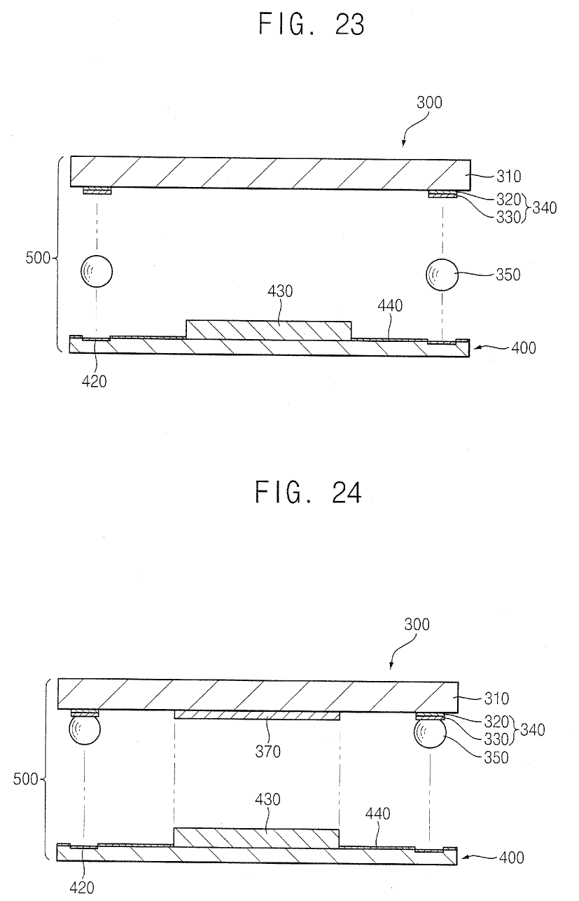

FIG. 23 is a cross-sectional view illustrating a method of manufacturing a semiconductor module in accordance with an eleventh example embodiment. The method of the present embodiment is substantially the same as that in Embodiment 10 except for an order of a reflow process on the heat-transferring member. Thus, the same reference numerals refer to same elements and any further illustrations of the same elements are omitted herein.

Referring to FIG. 23, after forming the heat-dissipating member 300, the heat-transferring member 350 is interposed between the attaching member 340 attached to the heat-dissipating body 310 and the land pattern 420 of the circuit substrate 400. After the heat-transferring member 350 is interposed between the attaching member 340 and the land pattern 420, the heat-transferring member 350 is melted in the infrared reflow furnace, so that the heat-transferring member 350 couples the attaching member 340 to the land pattern 420.

According to the present embodiment, the heat-transferring member 350 is simultaneously combined with the attaching member 340 and the land pattern 420 using only a single reflow process so that the time required for manufacturing the semiconductor module 500 may be remarkably reduced.

### Embodiment 12

FIG. 24 is an exploded cross-sectional view illustrating a method of manufacturing a semiconductor module in accordance with a twelfth example embodiment. The method of the present embodiment is substantially the same as that in Embodiment 10 except for a processing step for forming a heat-dissipating sheet. Thus, the same reference numeral refers to same elements and any further illustrations of the same elements are omitted herein.

Referring to FIG. 24, before assembling the circuit substrate 400 with the heat-dissipating member 300, a heat-transferring sheet 370 is interposed between the element 430 mounted on the circuit substrate 400 and the heat-dissipating body 310. In this example embodiment, the heat-transferring sheet 370 may be formed on the heat-dissipating body 310 facing the element 430. Alternatively, the heat-transferring sheet 370 may be formed on the element 430.

After the heat-transferring sheet 370 is interposed between the element 430 mounted to the circuit substrate 400 and the heat-dissipating body 310, the heat-transferring member 350 is combined with the land pattern 420 of the circuit substrate 400.

### Embodiment 13

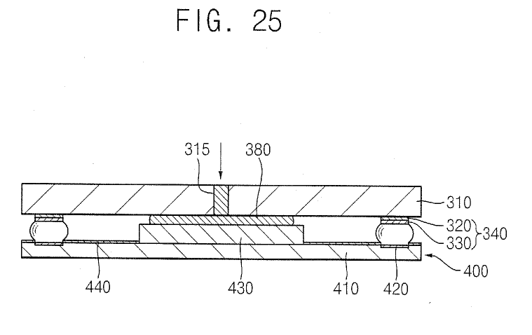

FIG. 25 is an exploded cross-sectional view illustrating a method of manufacturing a semiconductor module in accordance with a thirteenth example embodiment. The method of the present embodiment is substantially the same as that in Embodiment 10 except for a step for forming a heat-transferring layer. Thus, the same reference numerals refer to same elements and any further illustrations of the same elements are omitted herein.

Referring to FIG. 25, after assembling the attaching member 340 of the heat-dissipating member 300 with the land pattern 420 of the circuit substrate 400, a heat-transferring layer 380 is formed in a gap between the element 430 and the heat-dissipating body 310. To form the heat-dissipating layer 380 in the gap, one or more holes 315 are formed through the heat-dissipating body 310. In this example embodiment, the hole 315 is aligned with the element 430. A heat-transferring material having a relatively high thermal conductivity is then injected into the gap through the hole 315 to form the heat-transferring layer 380.

Accordingly, heat generated from the semiconductor element is rapidly removed so that the semiconductor element may have improved performance.

The foregoing is merely illustrative of the invention in its broader aspects and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A heat-dissipating member comprising:
a heat-dissipating body;
a heat-transferring member interposable between the heat-dissipating body and a heat source; and
an attaching member located on a surface of the heat-dissipating body to couple the heat-transferring member to the heat-dissipating body.

2. The heat-dissipating member of claim 1, wherein the heat-dissipating body comprises at least one selected from the group consisting of aluminum, aluminum alloy, copper and copper alloy.

3. The heat-dissipating member of claim 1, wherein the heat-transferring member comprises a conductive ball having a melting temperature lower than melting temperatures of the heat-dissipating body and the heat source.

4. The heat-dissipating member of claim 3, wherein the conductive ball comprises a solder ball.

5. The heat-dissipating member of claim 1, wherein the attaching member comprises a first layer formed on the heat-dissipating body and a second layer formed on the first layer.

6. The heat-dissipating member of claim 5, wherein the first layer comprises nickel and the second layer comprises gold.

7. The heat-dissipating member of claim 1, wherein the heat-dissipating body comprises at least one opening having a slit shape formed therethrough.

8. The heat-dissipating member of claim 7, wherein the at least one opening is arranged in substantially parallel with a relatively shorter side of the heat-dissipating body.

9. The heat-dissipating member of claim 1, wherein the heat-dissipating body includes a concave or convex portion.

10. A method of manufacturing a heat-dissipating member, the method comprising:
providing a heat-dissipating body to dissipate heat;
forming an attaching member on a surface of the heat-dissipating body; and
forming a heat-transferring member on the attaching member to transfer heat to the heat-dissipating body.

11. The method of claim 10, wherein forming the attaching member comprises:
forming a first layer on the heat-dissipating body; and
forming a second layer on the first layer.

12. The method of claim 11, wherein forming at least one of the first layer and the second layer comprises a plating process.

13. The method of claim 11, further comprising:
forming a photoresist pattern corresponding to the heat-transferring member on the second layer; and
etching the first and second layers, using the photoresist pattern as an etching mask, to form a first attaching pattern, and a second attaching pattern formed on the first attaching pattern.

14. The method of claim 11, wherein forming the attaching member further comprises attaching the second layer to the first layer using a second adhesive member.

15. The method of claim 14, wherein forming the attaching member comprises attaching the first layer to the heat-dissipating body using a first adhesive member.

16. The method of claim 15, wherein a thermal conductivity of at least one of the first and second adhesive members is substantially the same as that of the heat-dissipating body.

17. The method of claim 10, wherein forming the heat-transferring member comprises:
placing a conductive member on the attaching member; and
heating the conductive member to melt a boundary surface between the conductive member and the attaching member.

18. The method of claim 10, wherein preparing a heat-dissipating body comprises forming a concave or convex portion on the heat dissipating body.

19. A semiconductor module comprising:
a circuit substrate having a semiconductor element capable of generating heat during operation thereof;
a heat-dissipating body;
an attaching member placed on a surface of the heat-dissipating body; and
a heat-transferring member arranged and structured to couple the attaching member to the circuit substrate and thereby to transfer heat from the semiconductor element to the heat-dissipating body by way of the attaching member.

20. The module of claim 19, wherein the attaching member comprises:
a first layer including nickel; and
a second layer including gold formed on the first layer.

21. The module of claim 19, wherein the circuit substrate comprises a land pattern attached to the heat-transferring member.

22. The module of claim 19, wherein the heat-transferring member comprises solder.

23. The module of claim 19, wherein a height measured from the heat-dissipating body to the circuit substrate is substantially the same as a thickness of the semiconductor element.

24. The module of claim 19, further comprising a heat-transferring sheet interposed between the semiconductor element and the heat-dissipating body.

25. The module of claim 19, wherein the heat-dissipating body has a hole extending therethrough, the hole corresponding in position to a portion of an upper surface of the semiconductor element.

26. The module of claim 25, further comprising a fluid heat-transferring material disposed between the upper surface of the semiconductor element and the heat-dissipating body.

27. The module of claim 19, wherein the heat-dissipating body comprises an opening having a slit shape.

28. The module of claim 19, wherein the semiconductor element comprises:
a semiconductor chip;
a package substrate on which the semiconductor chip is mounted; and
a conductive ball to connect the package substrate and the circuit substrate.

29. The module of claim 19, wherein the heat-dissipating body is in direct contact with an upper surface of the element mounted on the circuit substrate.

30. A method of manufacturing a semiconductor module, the method comprising:
providing a heat-dissipating body;
forming an attaching member on the heat-dissipating body; and
attaching a circuit substrate, including a semiconductor element capable of generating heat, to the attaching member using a heat-transferring member.

31. The method of claim 30, wherein forming the attaching member comprises:
forming a first layer including nickel on the heat-dissipating body; and
forming a second layer including gold on an upper surface of the first layer.

32. The method of claim 30, wherein attaching the circuit substrate to the attaching member using the heat-transferring member comprises:
attaching the heat-transferring member to the attaching member; and
attaching the heat-transferring member to the circuit substrate.

33. The method of claim 30, wherein attaching the circuit substrate to the attaching member using the heat-transferring member comprises:
aligning the heat-transferring member between the attaching member and the circuit substrate; and
simultaneously attaching the attaching member and the circuit substrate to the heat-transferring member.

34. The method of claim 30, further comprising, before attaching the circuit substrate to the attaching member using the heat-transferring member, attaching a heat-transferring sheet to the heat-dissipating body facing the semiconductor element.

35. The method of claim 30, further comprising:
injecting a heat-transferring material into a gap between the heat-dissipating body and the semiconductor element.

36. The method of claim 30, wherein the heat-transferring material is injected into the gap formed through a hole extending through the heat-dissipating body.

37. The method of claim 30, wherein providing the heat-dissipating body comprises forming therein an opening having a slit shape.

38. A heat-dissipating member comprising:
a heat-dissipating body;
a heat-transferring member interposable between the heat-dissipating body and a heat source, the heat-transferring member having a melting temperature lower than melting temperatures of the heat-dissipating body and the heat source, and having a heat conductivity greater than or approximately equal to that of the heat-dissipating body; and
an attaching member located on a surface of the heat-dissipating body to align with the heat-transferring member to couple the heat-transferring member to the heat-dissipating body.

39. The heat-dissipating member of claim 38, wherein the heat-transferring member comprises a conductive ball.
